(19) United States
(12) Patent Application Publication
(10) Pub. No.: US 2026/0181975 A1
(43) Pub. Date: Jun. 25, 2026

(54) INTEGRATED CIRCUIT WITH GALVANIC ISOLATION STRUCTURE AND GATE DRIVER CIRCUIT

(71) Applicant: Infineon Technologis Austria AG, Villach (AT)

(72) Inventors: Dirk Manger, Dresden (DE); Lars Müller-Meskamp, Dresden (DE); Ralf Rudolf, Dresden (DE); Henning Feick, München (DE)

(21) Appl. No.: 19/424,803

(22) Filed: Dec. 18, 2025

(30) Foreign Application Priority Data
Dec. 20, 2024 (DE) 102024139449.8
Mar. 20, 2025 (DE) 102025110885.4

(51) Int. Cl. H10D 62/10; H10D 86/80

(52) U.S. Cl. CPC H10D 62/115; H10D 86/80

(57) ABSTRACT

An integrated circuit includes a semiconductor layer with a first portion in a first device region and a second portion in a second device region. A galvanic isolation structure is formed between the first portion and the second portion of the semiconductor layer. A capacitive coupling element is formed on a first surface of the semiconductor layer. The capacitive coupling element includes a first lower electrode in the first device region and a capacitor dielectric separating the first lower electrode from a top electrode spanning across the galvanic isolation structure. The first lower electrode is signal-connected to a first circuit element in the first device region. The top electrode is operatively connected to a second circuit element in the second device region.

### TECHNICAL FIELD

The present disclosure relates to high-voltage integrated circuits with separated device regions and to gate driver circuits.

### BACKGROUND

High-voltage integrated circuits in CMOS technology (complementary metal oxide semiconductors) typically include a low-voltage region to interface with low-voltage CMOS control and/or sensor circuits and a high-voltage region to control high-voltage switches or analyze high-voltage signals. Up to application voltages of several hundred Volts, lightly doped semiconducting voltage transition regions can separate the high-voltage region from the low-voltage region and internal high-voltage semiconducting elements transmit electric signals between the low-voltage region and the high-voltage region. At higher application voltages, such semiconducting voltage transition regions require considerably large chip area and it becomes increasingly difficult to avoid unwanted voltage breakdown between the high-voltage region and the low-voltage region.

There is a constant need to provide high voltage integrated circuits with high voltage breakdown capability and reliable internal data transmission.

### SUMMARY

An integrated circuit includes a semiconductor layer with a first portion in a first device region and a second portion in a second device region. A galvanic isolation structure is formed between the first portion and the second portion of the semiconductor layer. A capacitive coupling element is formed on a first surface of the semiconductor layer. The capacitive coupling element comprises a first lower electrode in the first device region and a capacitor dielectric separating the first lower electrode from a top electrode spanning across the galvanic isolation structure. The first lower electrode is signal-connected to a first circuit element in the first device region. The top electrode is operatively connected to a second circuit element in the second device region.

The galvanic isolation structure provides an area-efficient isolation structure for high nominal breakdown voltages. The capacitive coupling element ensures reliable signal transmission across the galvanic separation at predictable transmission parameters without impairing the galvanic isolation.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1A-1B illustrate a schematic vertical cross-sectional view and a corresponding horizontal cross-sectional view of a portion of an integrated circuit with a galvanic isolation structure and a capacitive coupling element for signal transmission across the galvanic isolation structure, in accordance with an embodiment related to a capacitive coupling element having a top electrode and a lower electrode.

FIG. 2A-2B illustrate a schematic vertical cross-sectional view and a corresponding horizontal cross-sectional view of a portion of an integrated circuit with a galvanic isolation structure and a capacitive coupling element for signal transmission across the galvanic isolation structure, in accordance with an embodiment related to a capacitive coupling element having a top electrode and two lower electrodes on both sides of the galvanic isolation structure.

FIG. 3 illustrates a schematic plan view of an integrated circuit with a galvanic isolation structure between a first device region and a second device region and with capacitive coupling elements for signal transmission between the first device region and the second device region, in accordance with an embodiment.

FIG. 4 illustrates a schematic vertical cross-sectional view of a portion of an integrated circuit with a top electrode of a capacitive coupling element formed in a topmost metal layer, in accordance with an embodiment.

FIG. 5 illustrates a schematic plan view of a portion of an integrated circuit with a capacitive coupling element having a top electrode with two electrode sections and a narrow connection section connecting the two electrode sections, in accordance with an embodiment.

FIG. 6A-6B illustrate a schematic vertical cross-sectional view and a corresponding horizontal cross-sectional view of a portion of an integrated circuit with a capacitive coupling element and with trench isolation structures laterally surrounding embedded regions of a semiconductor layer directly below the lower electrodes of the capacitive coupling element, in accordance with an embodiment.

FIG. 7A-7B illustrate a schematic vertical cross-sectional view and a corresponding horizontal cross-sectional view of a portion of an integrated circuit including a capacitive coupling element and guard lines partially surrounding the lower electrodes of the capacitive coupling element, in accordance with an embodiment.

FIG. 8 illustrates a schematic plan view of a portion of an integrated circuit with capacitive coupling elements and guard lines, in accordance with another embodiment.

FIG. 9 is a schematic block diagram of a gate driver circuit with capacitive coupling elements for passing differential data signals from a high-side part to a low-side part and from the low-side part to the high-side part in accordance with an embodiment.

### DETAILED DESCRIPTION

The terms “having”, “containing”, “including”, “including” and the like are open-ended, and the terms indicate the presence of certain structures, elements or features but do not preclude the presence of additional elements or features. The articles “a”, “an” and “the” include both the plural and singular, unless the context clearly indicates otherwise.

The expression “and/or” should be interpreted to cover all possible conjunctive and disjunctive combinations, unless expressly noted otherwise. For example, the expression “A and/or B” should be interpreted to mean A but not B, B but not A, or both A and B. The expression “at least one of” should be interpreted in the same manner as “and/or”, unless expressly noted otherwise. For example, the expression “at least one of A and B” should be interpreted to mean A but not B, B but not A, or both A and B.

The terms “electrically connected”, “signal-connected”, and “operatively connected” may include a direct connection or a connection through other electronic elements provided and suitable for permanent signal transmission, temporary signal transmission and/or transmission of energy. Electronic elements can be electrically connected, signal-connected and operatively connected via resistors, capacitors, semiconductor diodes, electronic switches such as field effect transistors, transistor circuits such as transmission gates, buffers and amplifiers, logic gates, inverters, opto-couplers, transformers, and others. At least one electrical signal in a second electrical circuit that is in signal-connection or operational connection with a first electrical circuit responds in a predictable, intended manner to a change of an electrical signal in the first electrical circuit. Directly electrically connected electronic elements are connected through a low-resistive wiring, an ohmic contact and/or a unipolar semiconductor junction.

An ohmic contact describes a non-rectifying electrical junction between two conductors, e.g., between a semiconductor material and a metal. The ohmic contact has a linear or approximately linear current-voltage (I-V) curve in the first and third quadrant of the I-V diagram as with Ohm's law.

Ranges given for physical dimensions include the boundary values. For example, a range for a parameter y from a to b reads as a≤y≤b. The same holds for ranges with one boundary value like “at most” and “at least”.

The term “on” is not to be construed as meaning only “directly on”. Rather, if one element is positioned “on” another element (e.g., a layer is “on” another layer or “on” a substrate), a further component (e.g., a further layer) may be positioned between the two elements (e.g., a further layer may be positioned between a layer and a substrate if the layer is “on” said substrate).

The examples described herein provide an integrated circuit that may include a semiconductor layer that may include a first portion in a first device region and a second portion in a second device region. A galvanic isolation structure may be formed between the first portion and the second portion of the semiconductor layer. A capacitive coupling element may be formed on a first surface of the semiconductor layer. The capacitive coupling element may include a first lower electrode in the first device region and a top electrode spanning across the galvanic isolation structure. A capacitor dielectric may separate the first lower electrode from the top electrode. The first lower electrode may be signal-connected to a first circuit element formed in the first device region. The top electrode may be operatively connected to a second circuit element formed in the second device region.

For example, a wiring connection may directly electrically connect an output of the first circuit element in the first device region with the first lower electrode. The first lower electrode is capacitively coupled to the top electrode. The top electrode is operatively connected with the second circuit element in the second device region.

The integrated circuit may be a HVIC, e.g., a controller for power factor correction, a gate driver circuit, a smart power conversion circuit including driver circuits for controlling high-voltage switches or a smart motor controller circuit, by way of example. The semiconductor layer may be or include a single-crystalline silicon layer with a uniform thickness. A planar or approximately planar first surface of the semiconductor layer extends in a horizontal plane and defines a front side of the semiconductor layer and the integrated circuit. A thickness of the semiconductor layer in a vertical direction orthogonal to the horizontal plane is uniform or approximately uniform.

The first device region and the second device region of the integrated circuit are formed adjacent to each other in the horizontal (lateral) direction. One of the device regions may partially or completely laterally enclose the other device region, or the two device regions may be arranged next to each other. For example, the first and second device regions may be approximately rectangular and are formed side-by-side at a uniform distance to each other.

The lateral extensions of the first and second device regions define the first and second portions of the semiconductor layer. The first portion of the semiconductor layer may be formed exclusively in the first device region. The second portion of the semiconductor layer may be formed exclusively in the second device region. The semiconductor layer may include a third portion outside the first and second device regions.

The galvanic isolation structure may be capable of withstanding a voltage of at least 200V, e.g. at least 600V, at least 900V, at least 1200V or at least 1700V without voltage breakdown. The rated breakdown voltage may be at least 600V, at least 900V, least 1200V or at least 1700V. The galvanic isolation structure may extend from the first surface of the semiconductor layer into and through the semiconductor layer down to a dielectric structure or a buried insulator layer formed on the rear side of the semiconductor layer. The galvanic isolation structure may include a single trench structure that may contain press-fitted doped or undoped glass or deposited dielectric material(s). Alternatively, the galvanic isolation structure may include a plurality of trench structures running parallel to each other. Vertical fins of the semiconductor layer or from another material may laterally separate neighboring trench structures from each other. Each trench structure may have a homogenous dielectric filling including, e.g. deposited silicon oxide and/or silicon oxynitride. Alternatively, each trench structure may include a dielectric liner covering a sidewall of a trench formed in the semiconductor layer, and a dielectric or semiconducting fill material deposited on the dielectric liner.

The galvanic isolation structure may laterally separate the first portion of the semiconductor layer in the first device region from the second portion of the semiconductor layer in the second device region. The galvanic isolation structure may be a line-shaped structure extending from one side of the semiconductor layer to the opposite side and cutting the semiconductor layer into the first portion and the second portions on opposite sides of the galvanic isolation structure. Alternatively, the galvanic isolation structure may form two closed loops, each closed loop laterally surrounding one of the first and second portions of the semiconductor layer.

An interlayer dielectric may separate the first lower electrode from the semiconductor layer. The interlayer dielectric may be a homogenous layer or may include two or more sublayers, wherein directly adjacent sublayers have a different material composition and/or density. For example, the interlayer dielectric may include a layer stack including a thermally grown silicon oxide, one or more layers of deposited silicon oxide, and/or one or more layers of a silicon nitride or a silicon oxynitride.

The first lower electrode may be a thin layer-like structure extending parallel to the first surface. A thickness of the first lower electrode may be in a range from 50 nm to 5 μm, e.g., from 0.1 μm to 1 μm. The first lower electrode may include an elementary transition metal like aluminum Al, copper Cu, tungsten W, titanium Ti or tantalum Ta, a metal alloy, or a transition metal nitride, e.g. titanium nitride TiN or tantalum TaN.

The first lower electrode may be formed in the lowest metal layer closest to the first surface of the semiconductor layer, in the second metal layer counted from the first surface, or in another metal layer between the lowest metal layer and a topmost metal layer. The first lower electrode may be a continuous structure without openings or may be grid-shaped.

The top electrode includes a section directly above the first lower electrode and spans across the galvanic isolation structure. The top electrode may have the same thickness as the first lower electrode, or may be significantly thicker than the first lower electrode. The top electrode may be formed from an elementary metal, a metal compound or metal alloy different from that of the first lower electrode.

The capacitor dielectric may separate the first lower electrode from the top electrode of the capacitive coupling element. The capacitor dielectric may be a homogenous layer or may include two or more sublayers, wherein directly adjacent sublayers have a different material composition and/or density. For example, the capacitor dielectric may include a layer stack including one or more layers of deposited silicon oxide and/or one or more layers of silicon nitride. The capacitor dielectric may have a rated breakdown voltage not lower than the rated breakdown voltage of the galvanic isolation structure.

The first circuit element signal-connected to the first lower electrode may be a driver stage of a single-ended driver or one of the two output stages of a differential driver. The first circuit element may be capable of driving a signal on a line directly connecting the output of the first circuit element and the first lower electrode, and charging/discharging the first lower electrode sufficiently fast for a predetermined signal transmission rate. The second circuit element operatively connected to the top electrode may be a receiver stage for a single-ended or one of two input stages of a differential signal receiver stage. The second circuit element may be capable of processing a signal received through a line directly connecting the top electrode with a receiver input of the second circuit element. Alternatively, the first circuit element may be capable of processing a signal received through a line directly connecting the top electrode with a receiver input of the first circuit element.

The galvanic isolation structure enables high nominal breakdown voltages on-chip and the capacitive coupling element may enable reliable signal transmission between the on-chip device regions at high data rates. Forming the capacitive coupling element requires only moderate changes in the production process of the integrated circuit. Component parameters of the capacitive coupling element, which determine the signal transmission properties, can be defined relatively narrowly with limited effort.

In accordance with an embodiment, the top electrode and the second circuit element formed in the second device region may be directly electrically connected. For example, a combination of metal wiring lines and through-vias may form a direct electrical connection from the top electrode to an input of the second circuit element.

In accordance with another embodiment, the capacitive coupling element may further include a second lower electrode formed in the second device region. The capacitor dielectric may further separate the second lower electrode from the top electrode. The second lower electrode is signal-connected to the second circuit element formed in the second device region.

The interlayer dielectric may separate both the first lower electrode and the second lower electrode from the semiconductor layer. The interlayer dielectric may be a homogenous layer or may include two or more sublayers, wherein directly adjacent sublayers have a different material composition and/or density. For example, the interlayer dielectric may include a layer stack including a thermally grown silicon oxide, one or more layers of deposited silicon oxide, and/or one or more layers of a silicon nitride or a silicon oxynitride.

The first lower electrode and the second lower electrode may be thin layer-like structures extending parallel to the first surface and may be formed in a same metal layer. A thickness of the first lower electrode and the second lower electrode may be in a range from 50 nm to 5 μm, e.g., from 0.1 μm to 1 μm. The first lower electrode and the second lower electrode may have the same lateral extensions or different lateral extensions and may include an elementary transition metal like aluminum Al, copper Cu, tungsten W, titanium Ti or tantalum Ta, a metal alloy, or a transition metal nitride, e.g. titanium nitride TiN or tantalum TaN.

The first lower electrode and the second lower electrode are laterally separated from each other by a portion of the interlayer dielectric, wherein the portion of the interlayer dielectric between the first lower electrode and the second lower electrode may have a rated breakdown voltage not lower than the rated breakdown voltage of the galvanic isolation structure. A lateral distance between the first lower electrode and the second lower electrode may be greater than a lateral width of the galvanic isolation structure along the same direction.

A vertical distance between the first lower electrode and the first surface of the semiconductor layer and a vertical distance between the second lower electrode and the first surface of the semiconductor layer may be equal. The first lower electrode and the second lower electrode may be formed in the lowest metal layer closest to the first surface of the semiconductor layer, in the second metal layer counted from the first surface, or in another metal layer between the lowest metal layer and a topmost metal layer. The first lower electrode and the second lower electrode may be continuous structures without openings or may be grid-shaped.

The top electrode includes sections directly above the first lower electrode and the second lower electrode, and spans across the galvanic isolation structure. The top electrode may have the same thickness as the lower electrodes, or may be significantly thicker than the lower electrodes. The top electrode may be formed from an elementary metal, a metal compound or metal alloy different from that of the first and second lower electrodes.

The capacitor dielectric may separate the first lower electrode and the second lower electrode from the top electrode of the capacitive coupling element. The capacitor dielectric may be a homogenous layer or may include two or more sublayers, wherein directly adjacent sublayers have a different material composition and/or density. For example, the capacitor dielectric may include a layer stack including one or more layers of deposited silicon oxide and/or one or more layers of silicon nitride. The capacitor dielectric may have a rated breakdown voltage not lower than the rated breakdown voltage of the galvanic isolation structure.

The first circuit element signal-connected to the first lower electrode may be a driver stage of a single-ended driver or one of the two output stages of a differential driver. The first circuit element may be capable of driving a signal on a line directly connecting the output of the first circuit element and the first lower electrode, and charging/discharging the first lower electrode sufficiently fast for a predetermined signal transmission rate. The second circuit element signal-connected to the second lower electrode may be a receiver stage for a single-ended or one of two input stages of a differential signal receiver stage. The second circuit element may be capable of processing a signal received through a line directly connecting the second lower electrode with a receiver input of the second circuit element. Alternatively, the first circuit element signal-connected to the first lower electrode may be a receiver stage for a single-ended or one of two input stages of a differential signal receiver stage. The first circuit element may be capable of processing a signal received through a line directly connecting the first lower electrode with a receiver input of the first circuit element.

The galvanic isolation structure enables high nominal breakdown voltages on-chip and the capacitive coupling element may enable reliable signal transmission between the on-chip device regions at high data rates. Forming the capacitive coupling element requires only moderate changes in the production process of the integrated circuit. Component parameters of the capacitive coupling element, which determine the signal transmission properties, can be defined relatively narrowly with limited effort.

In accordance with an embodiment, the galvanic isolation structure may extend from a first surface of the semiconductor layer into the semiconductor layer and insulate the first portion and the second portion of the semiconductor layer from each other up to a nominal breakdown voltage, or, alternatively, a specified nominal maximum working voltage, of at least 300V.

For example, the nominal breakdown voltage of the galvanic isolation structure may be at least 750V or 1200V. The galvanic isolation structure may structurally and electrically separate the first portion of the semiconductor layer in the first device region from the second portion of the semiconductor layer in the second device region in one or more lateral directions. In the vertical direction, the galvanic isolation structure may extend to or into an insulator layer formed on the backside of the semiconductor layer, wherein the first portion of the semiconductor layer in the first device region is electrically completely separated from the second portion of the semiconductor layer in the second device region.

In accordance with an embodiment, the top electrode may include a portion of a topmost metal layer of the integrated circuit.

The topmost metal layer may be formed from an elementary metal such as copper Cu, a metal compound or metal alloy, e.g. a copper alloy such as aluminum copper AlCu or aluminum silicon copper AlSiCu. Portions of the topmost metal layer other than the top electrode may form contact pads, e.g., for bond wires. The topmost metal layer may include a seed layer portion and an electroplated portion.

In accordance with an embodiment, a polyimide layer may cover the top electrode. The polyimide layer may cover the top electrode completely, may partially cover other portions of the topmost metal layer and may fill gaps between laterally separated portions of the topmost metal layer. Openings in the polyimide layer may expose other portions of the topmost metal layer. The polyimide layer may be formed directly on the top electrode, e.g., directly on the topmost metal layer and on portions of the capacitor dielectric exposed by the openings in the topmost metal layer. Alternatively, a dielectric or high-ohmic auxiliary layer may be formed directly on the topmost metal layer and on the portions of the capacitor dielectric exposed by the openings in the topmost metal layer, and the polyimide layer may be formed on the auxiliary layer. The auxiliary layer may be a homogenous layer or may include two or more sub-layers of different materials and/or structure. For example, the auxiliary layer may include a silicon nitride layer. The polyimide layer may contain additives tuning the mechanical and/or electrical properties of the polyimide layer.

In accordance with an embodiment, the top electrode may include a first electrode section in the first device region, a second electrode section in the second device region, and a narrow connection section connecting the first electrode section and the second electrode section.

The connection section may be narrower than the first electrode section and the second electrode section and may span across the galvanic isolation structure. Along a direction orthogonal to a shortest connection between the first portion and the second portion of the semiconductor layer, the connection section is narrower than each of the first electrode section and the second electrode section. The reduced width of the top electrode between the first and second electrode sections reduces parasitic capacitances and increases signal transmission efficiency. A comparatively small width of the connection section can be sufficient for the low displacement currents occurring in the top electrode during signal transmission.

In accordance with an embodiment, the connection section has a length along a direction directly connecting the first electrode section and the second electrode section in a horizontal plane parallel to the first surface of the semiconductor layer and a width w3 in the horizontal plane orthogonal to the length, the width w3 being smaller than first lateral extensions of the first electrode section and the second electrode section parallel to the width w3 of the connection section.

In case of a line-shaped galvanic isolation structure that includes a straight section directly between the first portion and the second portion of the semiconductor layer, the first electrode section has a first lateral extension w11 along a first direction parallel to the straight section of the line-shaped galvanic isolation structure, the second electrode section has a first lateral extension w21 along the first direction, and the width w3 of the connection section is smaller than the first lateral extensions w11, w21 of the first and second electrode sections. For example, the width w3 of the connection structure is at most 30% or at most 20% of the mean value of the first lateral extensions w11, w21 of the first and second electrode sections. Narrowing the connection section connecting the first and second electrode sections reduces parasitic capacitances and increases signal transmission efficiency.

In accordance with an embodiment, the first electrode section of the top electrode may laterally extend beyond the first lower electrode and/or the second electrode section of the top electrode may laterally extend beyond the second lower electrode.

The first electrode section may extend laterally on all sides beyond the first lower electrode. The second electrode section may extend laterally on all sides beyond the second lower electrode. The nominal lateral projection may be sufficiently large to compensate process-induced misalignments between the lower electrodes and the electrode sections of the top electrode.

For example, the first lower electrode and the first electrode section of the top electrode may be geometrically similar in the horizontal plane, and/or the second lower electrode and the second electrode section of the top electrode may be geometrically similar in the horizontal plane. The horizontal shape of the first electrode section may be obtained by scaling the horizontal shape of the first lower electrode with a scale factor greater 1 and/or the horizontal shape of the second electrode section may be obtained by scaling the horizontal shape of the second lower electrode with a scale factor greater 1. In addition, center points of the first lower electrode and the first electrode section of the top electrode may be concentric, i.e., on the same vertical axis. Center points of the second lower electrode and the second electrode section of the top electrode may be concentric, i.e., on the same vertical axis.

The larger electrode sections of the top electrode may compensate for process-related alignment errors between the lower electrodes and the electrode sections of the top electrode, so that the range of actual capacitance values of the capacitive coupling element is comparatively narrow and the data transmission rate via the capacitive coupling element is robust against production fluctuations in the formation of the top electrode.

In accordance with an embodiment, wherein a horizontal shape of the first electrode section parallel to the first surface and/or the second electrode section of the top electrode are rounded at a radius. of at least 5 μm.

For example, the horizontal shape of the first electrode section and/or the second electrode section forms a circle, an oval, or an ellipse. Alternatively, the horizontal shape of the first electrode section and/or the second electrode section is a polygon with rounded corners, e.g. a regular polygon with rounded corners. For example, the horizontal shape of the first electrode section and/or the second electrode section is a rectangle with rounded corners.

The absence of sharp corners and/or the rounding of corners reduces the electric field both in the polyimide layer and the capacitor dielectric and can contribute to higher reliability of the integrated circuit.

In accordance with an embodiment, the integrated circuit may further include a first trench isolation structure extending from the first surface into the semiconductor layer and laterally surrounding a first embedded region of the semiconductor layer directly below the first lower electrode and/or a second trench isolation structure extending from the first surface into the semiconductor layer and laterally surrounding a second embedded region of the semiconductor layer directly below the second lower electrode.

The first trench isolation structure may form a closed lateral frame around the first embedded region and/or the second isolation structure may form a closed lateral frame around the second embedded region. The first trench isolation structure may extend from the first surface through the semiconductor layer down to an insulator layer on the backside of the semiconductor layer to completely electrically separate the first embedded region from further regions of the first portion of the semiconductor layer outside the first embedded region. Alternatively or in addition, the second trench isolation structure may extend from the first surface through the semiconductor layer down to the insulator layer to completely electrically separate the second embedded region from further regions of the second portion of the semiconductor layer outside the second embedded region.

Each trench isolation structure may have a homogenous, dielectric fill, e.g. deposited silicon oxide or silicon oxynitride. Alternatively, each trench isolation structure may include a dielectric liner covering a sidewall of a trench formed in the semiconductor layer, and a fill material deposited on the dielectric liner. The fill material may be an isolator, e.g. an oxide or nitride, or a semiconducting material, e.g. doped or undoped polysilicon. Trench structures of a multi-part galvanic isolation structure and the trench isolation structures may have a similar configuration and may be formed sharing the same processes.

The inner edge of the first trench isolation structure may be shifted outwardly with respect to the outer edge of the first lower electrode and/or the inner edge of the second trench isolation structure may be shifted outwardly with respect to the outer edge of the second lower electrode in the horizontal directions. Accordingly, the horizontal cross-sectional area of the first embedded region can be greater than the horizontal cross-sectional area of the first lower electrode and/or the horizontal cross-sectional area of the second embedded region can be greater than the horizontal cross-sectional area of the second lower electrode.

In accordance with an embodiment, a first guard line may be formed along an edge of the first lower electrode and/or a second guard line may be formed along an edge of the second lower electrode.

The first guard line may be formed at a lateral distance from the first lower electrode, wherein the lateral distance between the first guard line and the first lower electrode may be uniform for the most part. The second guard line may be formed at a lateral distance from the second lower electrode, wherein the lateral distance between the second guard line and the second lower electrode may be uniform for the most part. The first guard line and the first lower electrode may be formed in the same metal layer. The second guard line and the second lower electrode may be formed in the same metal layer.

The first guard line may be formed along the entire circumference of the first lower electrode. Alternatively, the first guard line may be formed along all portions of the edge of the first lower electrode except for a portion of the edge directly facing the galvanic isolation structure. The second guard line may be formed along the entire circumference of the second lower electrode. Alternatively, the second guard line may be formed along all portions of the edge of the second lower electrode except for a portion of the edge directly facing the galvanic isolation structure. The guard lines may reduce the electric field outside the capacitive coupling element.

In accordance with an embodiment, the first guard line may be electrically connected to the first portion of the semiconductor layer in a lateral distance from the first lower electrode and/or the second guard line may be electrically connected to the second portion of the semiconductor layer in a lateral distance from the second lower electrode.

An ohmic contact between the first guard line and the semiconductor layer may be formed outside the first trench isolation structure that laterally surrounds the first embedded region directly below the lower electrode. An ohmic contact between the second guard line and the semiconductor layer may be formed outside the second trench isolation structure that laterally surrounds the second embedded region directly below the lower electrode.

Connecting the guard lines to a fixed potential facilitates a discharge of the displacement currents of the capacitive coupling element.

In accordance with an embodiment, the first conductive guard line and the first lower electrode may be formed from different sections of a lower electrode metal layer, and/or the second conductive guard line and the second lower electrode are formed from different sections of the lower electrode metal layer.

The lower electrode metal layer may be the first or second metal layer counted from the first surface of the semiconductor layer.

In accordance with an embodiment, the integrated circuit may further include a first feed line connecting the first circuit element and the first lower electrode, wherein the first guard line and a pass section of the first feed line crossing the first guard line are formed in different metal layers. Alternatively or in addition the integrated circuit may further include a second feed line connecting the second circuit element and the second lower electrode, wherein the second guard line and a pass section of the second feed line crossing the second guard line are formed in different metal layers.

In accordance with an embodiment, the integrated circuit may further include an insulator layer formed on a side of the semiconductor layer opposite the first surface.

In particular, the integrated circuit may be a semiconductor-on-insulator device. The insulator layer may be a silicon oxide layer with a thickness between 2 μm and 10 μm. The galvanic isolation structure may extend from the first surface of the semiconductor layer to or into the insulator layer. The first and second trench isolation structures may extend from the first surface of the semiconductor layer to or into the insulator layer.

In the absence of an insulator layer, the first embedded region may include a deep counter-doped region extending in a distance from a first surface at the front side of the semiconductor layer across the complete cross-sectional area of the first embedded region. Alternatively or in addition, the second embedded region may include a deep counter-doped region extending in a distance from the first surface at the front side of the semiconductor layer across the complete cross-sectional area of the second embedded region. The counter-doped regions may be n conductive for a p conductive semiconductor layer. Then the first trench isolation structure may extend from the first surface down to or into the counter-doped region to separate the first embedded region from further regions of the first portion of the semiconductor layer outside the first embedded region. Alternatively or in addition, the second trench isolation structure may extend from the first surface down to or into the counter-doped region to separate the second embedded region from further regions of the second portion of the semiconductor layer outside the second embedded region.

The integrated circuit may include one or more additional layers on the side of the insulator layer opposite the semiconductor layer. A tape and/or a handle substrate may be applied or formed on the side of the insulator layer opposite the semiconductor layer.

Other examples described herein provide a gate driver circuit that may include a semiconductor layer that may include a first portion in a first device region and a second portion in a second device region. A galvanic isolation structure may be formed between the first portion and the second portion of the semiconductor layer. A capacitive coupling element may be formed on a first surface of the semiconductor layer. The capacitive coupling element may include a first lower electrode in the first device region, a second lower electrode in the second device region and a top electrode. A capacitor dielectric may separate the first lower electrode and the second lower electrode from the top electrode. The first lower electrode may be signal-connected to a first circuit element formed in the first device region. The second lower electrode may be signal-connected to a second circuit element formed in the second device region.

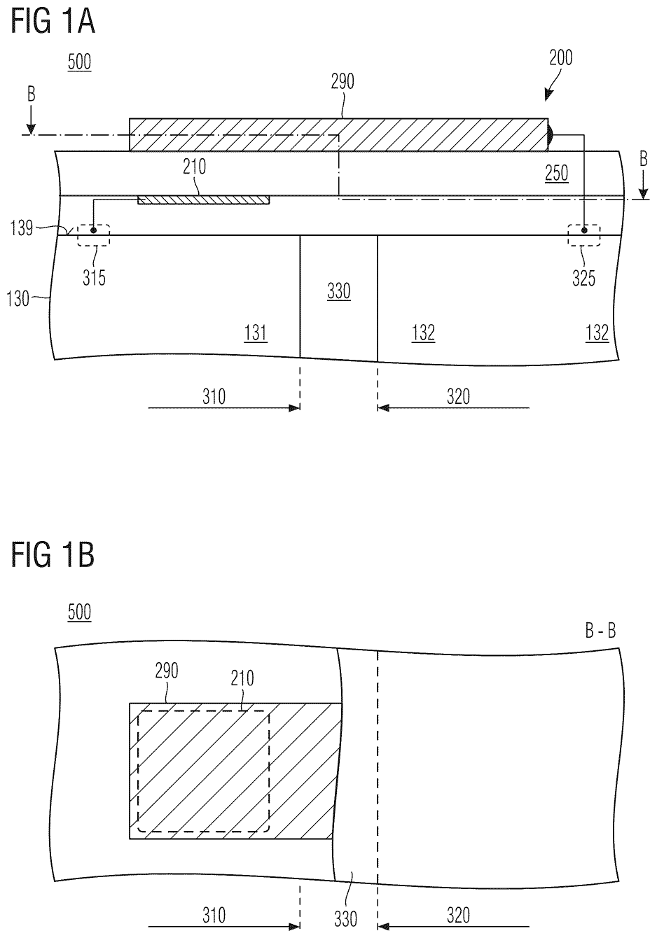

FIG. 1A and FIG. 1B show an integrated circuit 500 with a first device region 310 and a second device region 320 on opposite sides of an intermediate galvanic isolation structure 330 formed in a semiconductor layer 130. A first surface 139 at the front side of the semiconductor layer 130 defines a horizontal plane. A vertical direction runs orthogonal to the horizontal plane.

The galvanic isolation structure 330 laterally separates the semiconductor layer 130 into a first portion 131 in the first device region 310 and a second portion 132 in the second device region 320. A first circuit element 315 in the first device region 310 includes doped regions formed in the first portion 131 of the semiconductor layer 130. A second circuit element 325 in the second device region 320 includes doped regions formed in the second portion 132 of the semiconductor layer 130. The semiconductor layer 130 is a single-crystalline silicon layer. An interlayer dielectric 140 is formed directly on the first surface 139. The interlayer dielectric 140 is a homogenous layer or a layer stack including two or more dielectric layers, e.g., from silicon oxide, silicon nitride and/or silicon oxynitride.

A capacitive coupling element 200 is formed on the interlayer dielectric 140. A first lower electrode 210 of the capacitive coupling element 200 is formed on a portion of the interlayer dielectric 140 in the first device region 310. A capacitor dielectric 250 of the capacitive coupling element 200 is formed on the first lower electrode 210. The capacitor dielectric 250 may laterally extend beyond the outer edge of the first lower electrode 210 averted from the galvanic isolation structure 330. The capacitor dielectric 250 may be a homogenous layer from a single dielectric material or a layer stack including layers of different dielectric materials such as silicon oxide and silicon nitride. A thickness of the capacitor dielectric 250 may be in a range from 800 nm to 2 μm for a nominal breakdown voltage of 300V up to a range from 5 μm to 10 μm for a nominal breakdown voltage of 1200V. A top electrode 290 of the capacitive coupling element 200 is formed on the capacitor dielectric 250.

In the illustrated example, the shape of the first lower electrode 210 in the horizontal cross-section is a rectangle and the shape of the top electrode 290 in the horizontal cross-section is a rectangle with an area greater than the total area of the first lower electrode 210. At least 90%, e.g. 100%, of the vertical projection of a portion of the top electrode 290 in the first device region 310 into the plane of the first lower electrode 210 overlap with the first lower electrode 210.

The first circuit element 315 is a driver circuit for a digital signal. A conductor line connects a driver output of the first circuit element 315 with the first lower electrode 210 of the capacitive coupling element 200. The second circuit element 325 is a receiver circuit for a digital signal. A conductor line connects the top electrode 290 of the capacitive coupling element 200 with a receiver input of the second circuit element 325.

The capacitive coupling element 200 is in the transmission path from the first circuit element 315 to the second circuit element 325 and may have a capacitance in a range from 50 fF to 400 fF. A nominal breakdown voltage of the portion of the interlayer dielectric between the first and second lower electrodes 210, 220 and the capacitor dielectric 250 and a nominal breakdown voltage of the galvanic isolation structure 330 are in the same order of magnitude and greater 300V, 750V or 1200V.

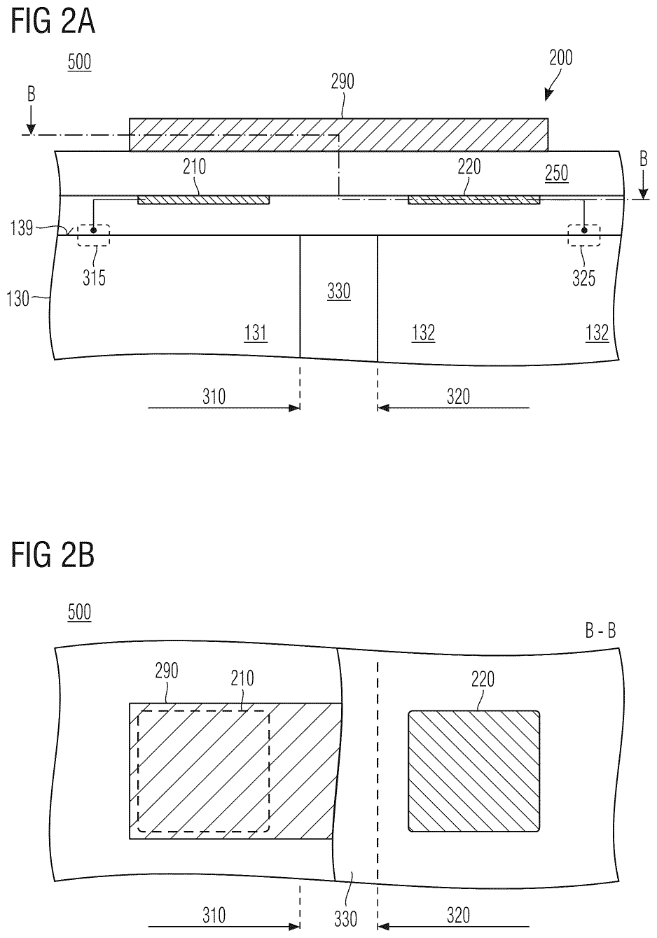

FIG. 2A and FIG. 2B show an integrated circuit 500 with a first device region 310 and a second device region 320 on opposite sides of an intermediate galvanic isolation structure 330 formed in a semiconductor layer 130. A first surface 139 at the front side of the semiconductor layer 130 defines a horizontal plane. A vertical direction runs orthogonal to the horizontal plane.

The galvanic isolation structure 330 laterally separates the semiconductor layer 130 into a first portion 131 in the first device region 310 and a second portion 132 in the second device region 320. A first circuit element 315 in the first device region 310 includes doped regions formed in the first portion 131 of the semiconductor layer 130. A second circuit element 325 in the second device region 320 includes doped regions formed in the second portion 132 of the semiconductor layer 130. The semiconductor layer 130 is a single-crystalline silicon layer. An interlayer dielectric 140 is formed directly on the first surface 139. The interlayer dielectric 140 is a homogenous layer or a layer stack including two or more dielectric layers, e.g., from silicon oxide, silicon nitride and/or silicon oxynitride.

A capacitive coupling element 200 is formed on the interlayer dielectric 140. A first lower electrode 210 of the capacitive coupling element 200 is formed on a portion of the interlayer dielectric 140 in the first device region 310. A second lower electrode 220 of the capacitive coupling element 200 is formed on a portion of the interlayer dielectric 140 in the second device region 310. Another portion of the interlayer dielectric 140 laterally separates the first lower electrode 210 from the second lower electrode 220. The first and second lower electrodes 210, 220 are formed at the same distance to the first surface 139. A capacitor dielectric 250 of the capacitive coupling element 200 is formed on the first lower electrode 210, the second lower electrode 220, and the portion of the interlayer dielectric 140 laterally separating the first lower electrode 210 from the second lower electrode 220. The capacitor dielectric 250 may laterally extend beyond the outer edges of the first and second lower electrodes 210, 220 averted from the galvanic isolation structure 330. The capacitor dielectric 250 may be a homogenous layer from a single dielectric material or a layer stack including layers of different dielectric materials such as silicon oxide and silicon nitride. A thickness of the capacitor dielectric 250 may be in a range from 800 nm to 2 μm for a nominal breakdown voltage of 300V up to a range from 5 μm to 10 μm for a nominal breakdown voltage of 1200V. A top electrode 290 of the capacitive coupling element 200 is formed on the capacitor dielectric 250.

In the illustrated example, the shape of the first and second lower electrodes 210, 220 in the horizontal cross-section is a rectangle and the shape of the top electrode 290 in the horizontal cross-section is a rectangle with an area greater than the total area of the first and second lower electrodes 210, 220. At least 90%, e.g. 100%, of the vertical projection of the top electrode 290 into the plane of the lower electrodes 210, 220 overlap with the first and second lower electrodes 210, 220.

The first circuit element 315 is a driver circuit for a digital signal. A conductor line connects a driver output of the first circuit element 315 with the first lower electrode 210 of the capacitive coupling element 200. The second circuit element 325 is a receiver circuit for a digital signal. A conductor line connects the second lower electrode 210 of the capacitive coupling element 200 with a receiver input of the second circuit element 325.

The capacitive coupling element 200 is in the transmission path from the first circuit element 315 to the second circuit element 325 and may have a capacitance in a range from 50 fF to 400 fF. A nominal breakdown voltage of the portion of the interlayer dielectric between the first and second lower electrodes 210, 220 and the capacitor dielectric 250 and a nominal breakdown voltage of the galvanic isolation structure 330 are in the same order of magnitude and greater 300V, 750V or 1200V.

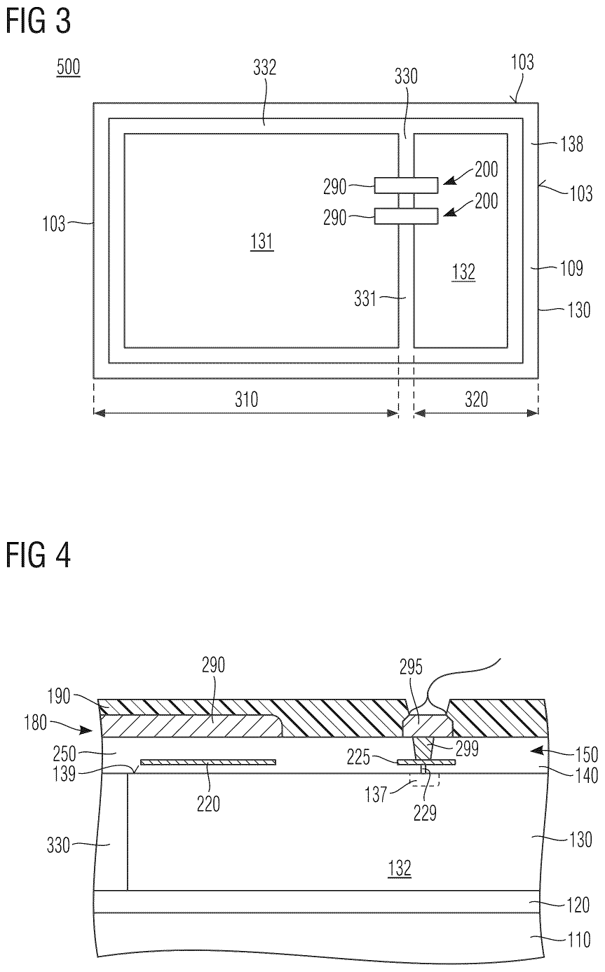

The integrated circuit 500 illustrated in FIG. 3 includes a galvanic isolation structure 330 that forms two closed loops, wherein each loop laterally surrounds one of the first and second portions 131, 132 of the semiconductor layer 130. A straight line section 331 of the galvanic isolation structure 330 laterally separates the first and second portions 131, 132 and defines first and second device regions 310, 320 on opposite sides of the straight line section 331. A frame section 332 forms a single frame around the first portion 131 and the second portion 132 and laterally separates the first and second portions 131, 132 from a third portion 138 of the semiconductor layer 130 between the frame section 332 and an outer lateral surface 103 of the integrated circuit 500. The integrated circuit 500 includes two capacitive coupling elements 200 with top electrodes 290 bridging the straight line section 331 of the galvanic isolation structure 330.

As shown in FIG. 4, the galvanic isolation structure 330 may extend from the first surface 139 through the semiconductor layer 130 down to an insulator layer 120 formed on the rear side of the semiconductor layer 130 opposite the first surface 139. The insulator layer 120 separates the semiconductor layer 130 from a substrate layer 110. An interlayer dielectric 140 is formed on the first surface 139. A second lower electrode 220 of a capacitive coupling element 200 is formed on the interlayer dielectric 140. A capacitor dielectric 250 of the capacitive coupling element 200 is formed on the second lower electrode 220. A top electrode 290 of the capacitive coupling element 200 is formed on the capacitor dielectric 250.

From a metal conductor 225, a metal contact 229 extends through the interlayer dielectric 140 to a doped contact region 137 in the second portion 132 of the semiconductor layer 130. The metal conductor 225 and the second lower electrode 220 are formed in the same lower electrode metal layer 150. From a metal contact pad 295 formed on the capacitor dielectric 250, another metal contact 299 extends through the capacitor dielectric 250 to the metal conductor 225. The contact pad 295 and the top electrode 290 are formed in the same topmost metal layer 180. A polyimide layer 190 covers the top electrode 290, sidewalls of the contact pad 295 and a portion of the capacitor dielectric 250 between the top electrode 290 and the contact pad 295. An opening in the polyimide layer 190 exposes a top surface of the contact pad 295.

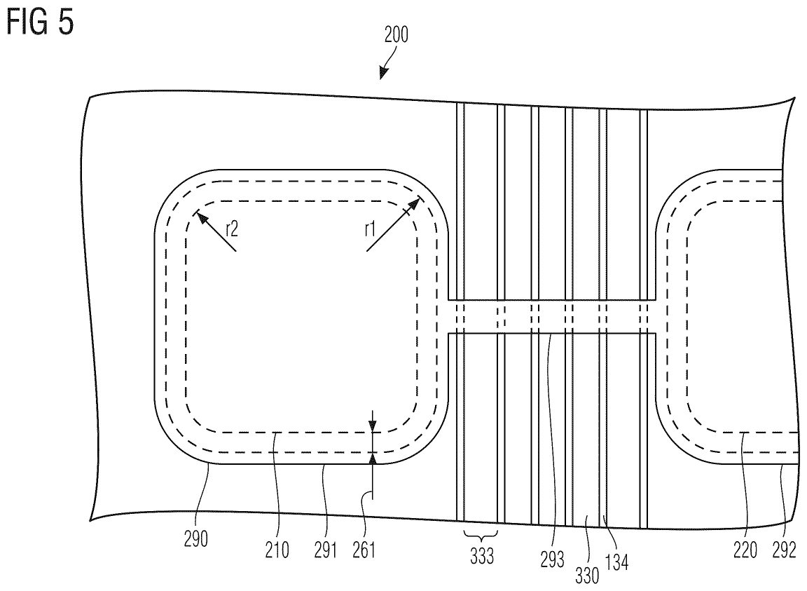

In FIG. 5, a top electrode 290 of a capacitive coupling element 200 includes a first electrode section 291 directly above the first lower electrode 210, a second electrode section 292 directly above the second lower electrode 220 and a connection section 293 connecting the first electrode section 291 and the second electrode section 292.

The horizontal shapes of the first lower electrode 210 and the first electrode section 291 are geometrically similar, wherein the horizontal shape of the first electrode section 291 is obtained by scaling the horizontal shape of the first lower electrode 210 with a scale factor greater 1 and shifting the shape along the vertical direction. The horizontal shapes of the second lower electrode 220 and the second electrode section 292 are geometrically similar, wherein the horizontal shape of the second electrode section 292 is obtained by scaling the horizontal shape of the second lower electrode 220 with a scale factor greater 1 and shifting the shape along the vertical axis. Both scale factors are equal. The shapes of the first lower electrode 210, the second lower electrode 220, the first electrode section 291, and the second electrode section 292 are rectangles with rounded corners. A rounding radius r1 of the corners of the first and second electrode sections 291, 292 may be in a range from 1 μm to 20 μm. A rounding radius r2 of the corners of the first and second lower electrodes 210, 220 may be in a range from 1 μm to 20 μm. The electrode sections 291, 292 of the top electrode 290 project beyond the lower electrodes 210, 220 on all sides to the same degree.

The connection section 293 spans across a multi-part galvanic isolation structure 300. Along a direction orthogonal to a shortest connection between the first electrode section 291 and the second electrode section 292 of the top electrode 290, the connection section 293 is narrower than each of the first electrode section 291 and the second electrode section 292. The width of the connection section 293 is less than 20% of the corresponding width of the first and second electrode sections 291, 292.

The straight line section of the multi-part galvanic isolation structure 300 includes four parallel trench structures 333 laterally separated by semiconductor fins 334 formed from portions of the semiconductor layer 130. The trench structures 333 have identical widths and extend parallel to each other. Each two of the trench structures 333 may form one of the loops illustrated in FIG. 3.

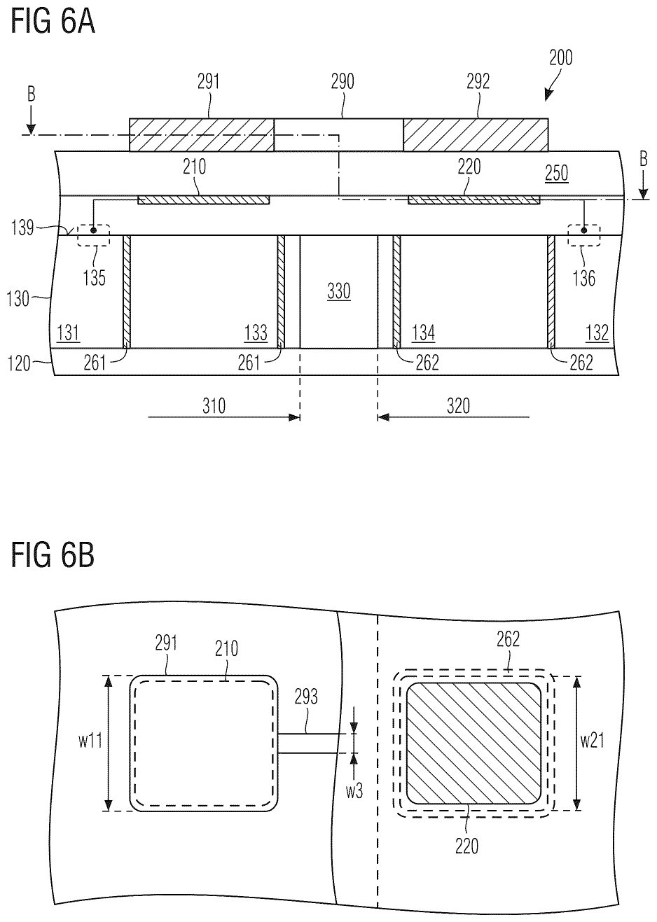

FIG. 6A further shows a first trench isolation structure 261 that extends from the first surface 139 through the semiconductor layer 130 down to the insulator layer 120 and laterally surrounds a first embedded region 133 of the semiconductor layer 130 directly below the first lower electrode 210. A second trench isolation structure 262 extends from the first surface 139 through the semiconductor layer 130 to the insulator layer 120 and laterally surrounds a second embedded region 134 of the semiconductor layer 130 directly below the second lower electrode 220.

As illustrated in FIG. 6B, the first trench isolation structure 261 forms a closed frame around the first embedded region 133. The second isolation structure 262 forms a closed frame around the second embedded region 134. For further details, reference is made to the description of FIG. 2A and FIG. 2B.

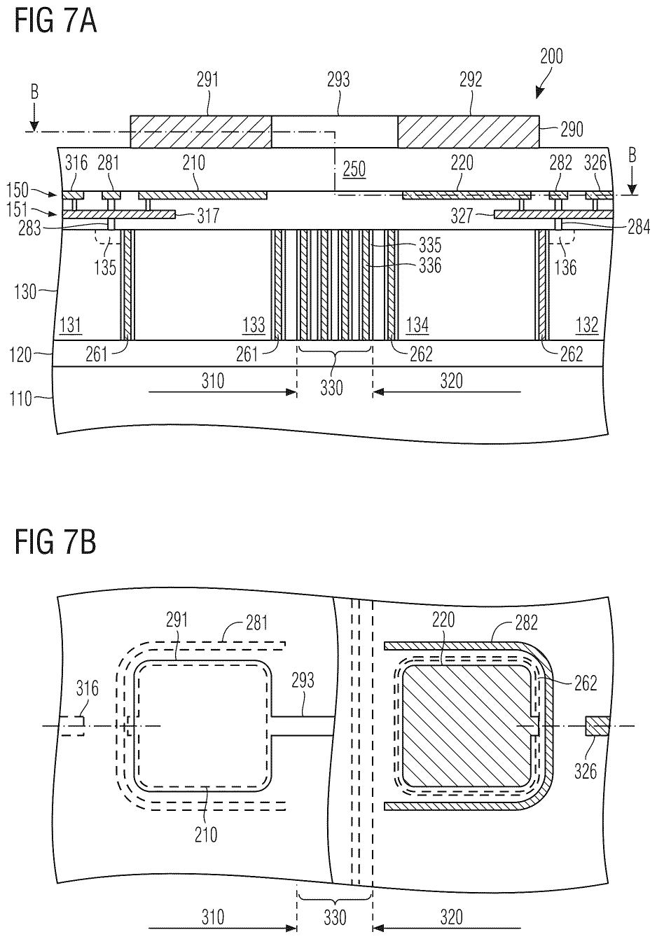

FIGS. 7A-7B show a multi-part galvanic isolation structure 330 including three parallel trench structures 333 in a straight line section 331 between the first portion 131 and the second portion 132 of the semiconductor layer 130. The different trench structures 333 have the same lateral and vertical dimensions and the same configuration. Each trench structure 333 includes a dielectric liner 335 lining at least sidewalls of a trench that extends from the first surface 139 into the semiconductor layer 130, and a filling 336. The dielectric liner 335 may include a silicon oxide. The filling 336 may include a dielectric or semiconducting material, e.g. polycrystalline silicon, deposited on the dielectric liner 335. The trench structures 333 and the isolation structures 261, 262 may have the same width and configuration.

A first guard line 281 is formed along an edge of the first lower electrode 210. The first guard line 281 is formed in the lower electrode metal layer 150 at a lateral distance from the first lower electrode 210, wherein the lateral distance between the first guard line 281 and the first lower electrode 210 may be uniform at least for the most part. The first guard line 281 extends along all sides of the first lower electrode 210 except the side facing directly the galvanic isolation structure 330.

A second guard line 282 is formed along an edge of the second lower electrode 220. The second guard line 282 is formed in the lower electrode metal layer 150 at a lateral distance from the second lower electrode 220, wherein the lateral distance between the second guard line 282 and the second lower electrode 220 may be uniform at least for the most part. The second guard line 282 extends along all sides of the second lower electrode 220 except the side facing directly the galvanic isolation structure 330.

A first guard line contact 283 electrically connects the first guard line 281 with a doped first guard line contact region 135 that is formed in a region of the first portion 131 of the semiconductor layer 130 outside the first embedded region 133. The first guard line contact 283 and the first guard line contact region 135 form an ohmic contact.

A second guard line contact 284 electrically connects the second guard line 282 with a doped second guard line contact region 136 that is formed in a region of the second portion 132 of the semiconductor layer 130 outside the second embedded region 134. The second guard line contact 284 and the second guard line contact region 136 form an ohmic contact.

A first feed line 316 connecting the first circuit element 315 illustrated in FIGS. 7A-7B and the first lower electrode 210 includes a main section formed in the lower electrode metal layer 150 and a pass section 317 formed in an auxiliary metal layer 151. The pass section 317 of the first feed line 316 and the first guard line 281 cross each other in different metal planes. A first feed line contact connects the main section of the first feed line 316 with the pass section 317 and a second feed line contact connects the first lower electrode 210 with the pass section 317.

A second feed line 326 connecting the second circuit element 325 illustrated in FIGS. 7A-7B and the second lower electrode 220 includes a main section formed in the lower electrode metal layer 150 and a pass section 327 formed in the auxiliary metal layer 151. The pass section 327 of the second feed line 326 and the second guard line 282 cross each other in different metal planes. A second feed line contact connects the main section of the second feed line 326 with the pass section 327 of the second feed line 326 and a second feed line contact connects the second lower electrode 220 with the pass section 327 of the second feed line 326.

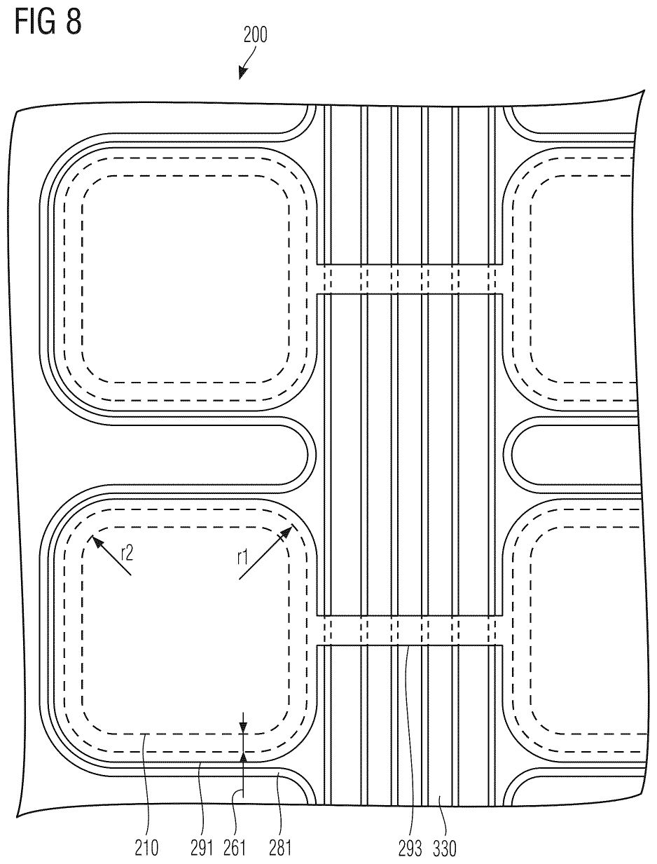

FIG. 8 combines guard lines 281, 282 as illustrated in FIG. 7A and FIG. 7B with capacitive coupling elements 200 as illustrated in FIG. 5. A single first guard line 281 and a single second guard line 282 may be provided for electrode sections of a plurality of capacitive coupling elements 200 formed side-by-side along the straight line section of the galvanic isolation structure 330. Guard lines with sections formed directly between neighboring electrode sections of the same device region may reduce crosstalk between signals transmitted via the neighboring capacitive coupling elements 200.

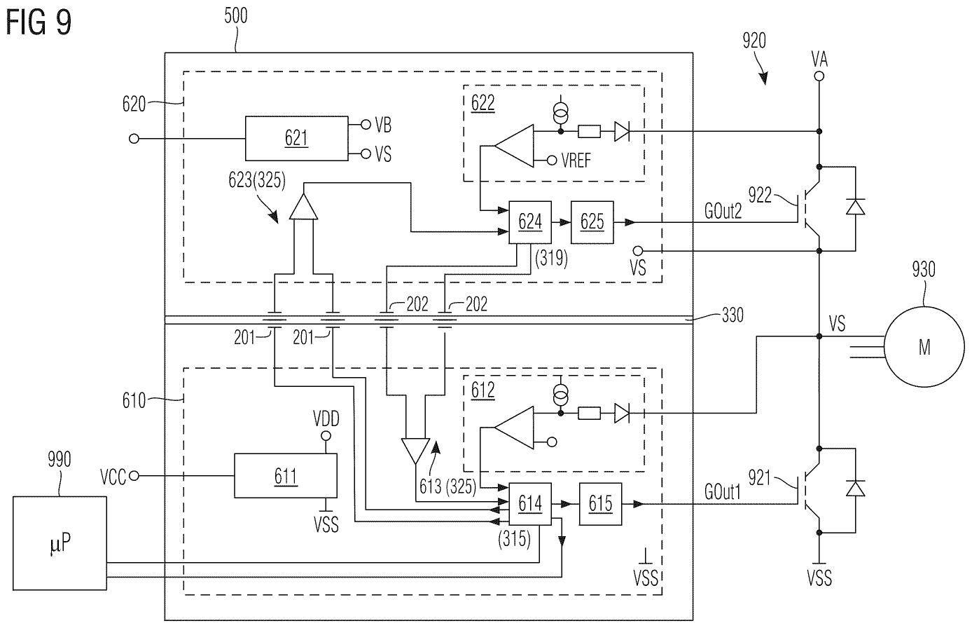

FIG. 9 shows an integrated circuit 500 configured as gate driver circuit in silicon-on-insulator technology. The integrated circuit 500 includes a high side part 620 configured to drive a gate of a high side switch 922 of a half bridge and a low side part 610 configured to drive a gate of a low side switch 921 of the half bridge. A galvanic isolation structure 330 as described above galvanically separates the high side part 620 from the low side part. The integrated circuit 500 includes a high side power supply circuit 621 to obtain a positive power supply voltage VB for the high side part 620 (high side supply potential VB). The positive power supply voltage VB for the high side part 620 is referenced to a high side reference potential VS, which may correspond to the potential of the switching node of a half bridge 920.

A high side desaturation detection circuit 622 is connected to the supply potential VA of the half bridge 920, detects a desaturation of the high side switch 922 of the half bridge 920, and outputs a high side desaturation signal indicating whether a desaturation condition exists. A high side receiver circuit 623 includes second circuit elements 325 as described above for receiving a differential gate control signal via two first capacitive coupling elements 201 as described above and outputs a single-ended high side gate control signal. A logic circuit 624 in the high side part 620 receives the high side desaturation signal and the high side gate control signal. The logic circuit 624 in the high side part 620 outputs a second gate drive signal Gout2 in response to the high side gate control signal provided that the high side desaturation signal does not indicate a desaturation condition. A high side driver stage 625 may drive the second gate drive signal Gout2.

The logic circuit 624 in the high side part further includes first circuit elements 315 as described above for outputting a differential high side data signal. Two second capacitive coupling elements 202 as described above transmit the differential high side data signal from the high side part 620 to a low side receiver circuit 613 in the low side part 610.

The low side part 610 of the gate driver circuit includes a low side power supply circuit 611 to obtain a positive power supply voltage VDD for the low side part 610. The positive power supply voltage VDD for the low side part 610 is referenced to the first reference potential VSS.

A low side desaturation detection circuit 612 is connected to the output node of the half bridge 920, detects a desaturation of the low side switch 921, and outputs a low side desaturation signal indicating whether a desaturation condition exists. The low side receiver circuit 613 includes second circuit elements 325 as described above for receiving a differential low side data signal from the two second capacitive coupling elements 202 and outputs a single-ended low side data signal. A logic circuit 614 in the low side part 610 receives the low side data signal, the low side desaturation signal, and a low side gate control signal from an external source like a processor 990. The logic circuit 614 in the low side part 610 outputs a first gate drive signal Gout1 in response to the low side gate control signal provided that none of the low side desaturation signal and the low side data signal indicates a desaturation condition. A low side driver stage 615 drives the first gate drive signal Gout1.

The logic circuit 614 in the low side part 610 further includes first circuit elements 315 as described above that output a differential gate control signal. The two first capacitive coupling elements 201 transmit the differential gate control signal from the low side part 610 to the high side part 620. An inductive load 930 is electrically connected between the switching nodes of two half bridges 920.

The first and second capacitive coupling elements 201, 202 having any of the configurations of the present embodiments enable the signal transfer between the low side part 610 and the high side part 620 and can be formed in a way that the transmission parameters are robust against process variations.

Although specific examples have been illustrated and described herein, it will be appreciated by those of ordinary skill in the art that a variety of alternate and/or equivalent implementations may be substituted for the specific examples shown and described without departing from the scope of the present invention. This application is intended to cover any adaptations or variations of the specific examples discussed herein. Therefore, it is intended that this invention be limited only by the claims and the equivalents thereof.

It should be noted that the integrated circuit including its preferred embodiments as outlined in the present document may be used stand-alone or in combination with the other integrated circuits disclosed in this document. In addition, the features outlined in the context of an integrated circuit are also applicable to a corresponding method, and vice versa. Furthermore, all aspects of the integrated circuits outlined in the present document may be arbitrarily combined. In particular, the features of the claims may be combined with one another in an arbitrary manner.

What is claimed is:

1. An integrated circuit, comprising:
a semiconductor layer comprising a first portion in a first device region and a second portion in a second device region;
a galvanic isolation structure formed between the first portion and the second portion of the semiconductor layer; and
a capacitive coupling element formed on a first surface of the semiconductor layer,
wherein the capacitive coupling element comprises a first lower electrode in the first device region and a capacitor dielectric separating the first lower electrode from a top electrode spanning across the galvanic isolation structure,
wherein the first lower electrode is signal-connected to a first circuit element formed in the first device region and the top electrode is operatively connected to a second circuit element formed in the second device region.

2. The integrated circuit of claim 1,
wherein the top electrode and the second circuit element formed in the second device region are directly electrically connected.

3. The integrated circuit of claim 1,
wherein the capacitive coupling element further comprises a second lower electrode in the second device region,
wherein the capacitor dielectric further separates the second lower electrode from the top electrode, and
wherein the second lower electrode is signal-connected to the second circuit element formed in the second device region.

4. The integrated circuit of claim 1,
wherein the galvanic isolation structure extends from a first surface of the semiconductor layer into the semiconductor layer and insulates the first portion and the second portion of the semiconductor layer from each other up to a breakdown voltage of at least 200V.

5. The integrated circuit of claim 1,
wherein the top electrode comprises a portion of a topmost metal layer of the integrated circuit.

6. The integrated circuit of claim 1, further comprising:
a polyimide layer covering the top electrode.

7. The integrated circuit of claim 1,
wherein the top electrode comprises a first electrode section in the first device region, a second electrode section in the second device region, and a narrow connection section connecting the first electrode section and the second electrode section.

8. The integrated circuit of claim 7,
wherein the narrow connection section has a length along a direction directly connecting the first electrode section and the second electrode section in a horizontal plane parallel to the first surface of the semiconductor layer and a width in the horizontal plane orthogonal to the length extension, the width being smaller than horizontal extensions of the first electrode section and the second electrode section parallel to the width of the connection section.

9. The integrated circuit of claim 7,
wherein the first electrode section of the top electrode laterally extends beyond the first lower electrode and/or the second electrode section of the top electrode laterally extends beyond the second lower electrode.

10. The integrated circuit of claim 7,
wherein a horizontal shape of the first electrode section parallel to the first surface and/or the second electrode section of the top electrode are rounded at a radius of at least 5 μm.

11. The integrated circuit of claim 1, further comprising:
a trench isolation structure extending from the first surface into the semiconductor layer and laterally surrounding an embedded region of the semiconductor layer directly below the first lower electrode.

12. The integrated circuit of claim 1, further comprising:
a trench isolation structure extending from the first surface into the semiconductor layer and laterally surrounding an embedded region of the semiconductor layer directly below the second lower electrode.

13. The integrated circuit of claim 1, further comprising:
a first guard line formed along an edge of the first lower electrode and/or a second guard line formed along an edge of the second lower electrode.

14. The integrated circuit of claim 13,
wherein the first guard line is electrically connected to the first portion of the semiconductor layer in a lateral distance from the first lower electrode and/or the second guard line is electrically connected to the second portion of the semiconductor layer in a lateral distance from the second lower electrode.

15. The integrated circuit of claim 13,
wherein the first conductive guard line and the first lower electrode are formed from different sections of a lower electrode metal layer, and/or
wherein the second conductive guard line and the second lower electrode are formed from different sections of a lower electrode metal layer.

16. The integrated circuit of claim 13, further comprising:
a first feed line connecting the first circuit element and the first lower electrode, wherein the first guard line and a pass section of the first feed line crossing the first guard line are formed in different metal layers; and/or
a second feed line connecting the second circuit element and the second lower electrode, wherein the second guard line and a pass section of the second feed line crossing the second guard line are formed in different metal layers.

17. The integrated circuit of claim 1, further comprising:
an insulator layer formed on a side of the semiconductor layer opposite the first surface.

18. A gate driver circuit, comprising:
a semiconductor layer comprising a first portion in a first device region and a second portion in a second device region;
a galvanic isolation structure formed between the first portion and the second portion of the semiconductor layer; and
a capacitive coupling element formed on a first surface of the semiconductor layer,
wherein the capacitive coupling element comprises a first lower electrode in the first device region, a second lower electrode in the second device region, and a capacitor dielectric separating the first lower electrode and the second lower electrode from a top electrode,
wherein the first lower electrode is signal-connected to a first circuit element formed in the first device region and the second lower electrode is signal-connected to a second circuit element formed in the second device region.

19. The gate driver circuit of claim 18, further comprising:
a guard line formed along an edge of the first lower electrode,
wherein the guard line is electrically connected to the first portion of the semiconductor layer in a lateral distance from the first lower electrode.

20. The gate driver circuit of claim 18, further comprising:
a guard line formed along an edge of the second lower electrode,
wherein the guard line is electrically connected to the second portion of the semiconductor layer in a lateral distance from the second lower electrode.
